(19) United States
(12) Patent Application Publication
(10) Pub. No.: US 2014/0002750 A1
(43) Pub. Date: Jan. 2, 2014

(54) TELEVISION RECEIVER AND ELECTRONIC DEVICE

(71) Applicant: Kabushiki Kaisha Toshiba, Tokyo (JP)

(72) Inventor: Tomohiro HAMADA, Tachikawa-shi (JP)

(21) Appl. No.: 14/018,690

(22) Filed: Sep. 5, 2013

Related U.S. Application Data
(63) Continuation of application No. PCT/JP2013/057935, filed on Mar. 13, 2013.

(30) Foreign Application Priority Data
May 31, 2012 (JP) 2012-124994

(51) Int. Cl. H05K 7/20

(52) U.S. Cl. CPC H05K 7/202
USPC 348/725; 361/695

(57) ABSTRACT

According to one embodiment, a television receiver includes: a display device; a housing; a fan unit; a first wall; a second wall; and a supporting structure. The display device includes a display screen. The housing houses at least a portion of the display device. The fan unit is positioned in the housing and positioned opposite the display screen with respect to the display device, and includes a rotating portion including a fan. The first wall extends in a direction intersecting a rotation axis of the fan on a side opposite the display screen with respect to the fan. The second wall extends in the direction intersecting the rotation axis on a side opposite the first wall with respect to the fan. The supporting structure is positioned between the first wall and the second wall at apart at which rotation center of the rotating portion is positioned.

### CROSS-REFERENCE TO RELATED APPLICATIONS

This application is a continuation of PCT international application Ser. No. PCT/JP2013/057935, filed on Mar. 13, 2013, which designates the United States, incorporated herein by reference, and which is based upon and claims the benefit of priority from Japanese Patent Application No. 2012-124994, filed on May 31, 2012, the entire contents of which are incorporated herein by reference.

### FIELD

Embodiments described herein relate generally to a television receiver and an electronic device.

### BACKGROUND

Conventionally, there is known an electronic device that is provided with a fan in a housing thereof.

In the electronic device to which the fan is provided, it is unfavorable that inconveniences such that rotation of the fan becomes difficult due to external force acting on the housing occurs.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of a television receiver according to a first embodiment;

FIG. 2 is an exemplary side view of the television receiver in the first embodiment;

FIG. 3 is an exemplary schematic cross-sectional view of the television receiver as viewed along the line in FIG. 1, in the first embodiment;

FIG. 4 is an exemplary plan view of a rotating portion comprised in the television receiver in the first embodiment;

FIG. 5 is an exemplary front view of a fan unit comprised in the television receiver in the first embodiment;

FIG. 6 is an exemplary perspective view of an electronic device according to a second embodiment;

FIG. 7 is an exemplary plan view (bottom view) of a second housing of the electronic device in the second embodiment;

FIG. 8 is an exemplary cross-sectional view taken along the line VIII-VIII in FIG. 7 in the second embodiment;

FIG. 9 is an exemplary cross-sectional view of an electronic device as viewed at a position equivalent to that in FIG. 8, according to a third embodiment;

FIG. 10 is an exemplary cross-sectional view of an electronic device as viewed at a position equivalent to that in FIG. 8, according to a fourth embodiment;

FIG. 11 is an exemplary cross-sectional view of an electronic device as viewed at a position equivalent to that in FIG. 8, according to a fifth embodiment; and

FIG. 12 is an exemplary cross-sectional view of a portion of an electronic device according to a sixth embodiment.

### DETAILED DESCRIPTION

In general, according to one embodiment, a television receiver comprises: a display device; a housing; a fan unit; a first wall; a second wall; and a supporting structure. The display device comprises a display screen. The housing is configured to house therein at least a portion of the display device. The fan unit is configured to be positioned in the housing and positioned opposite the display screen with respect to the display device. The fan unit comprises a rotating portion comprising a fan. The first wall extends in a direction intersecting a rotation axis of the fan on a side opposite the display screen with respect to the fan. The second wall extends in the direction intersecting the rotation axis on a side opposite the first wall with respect to the fan. The supporting structure is configured to be positioned between the first wall and the second wall at a part at which rotation center of the rotating portion is positioned.

A plurality of exemplary embodiments in the following comprise the same or similar configuration elements. Accordingly, in the following description, the same or similar configuration elements are given with common reference numerals or symbols, and redundant explanations are omitted.

While the following embodiments describe examples in which an electronic device is configured as a television receiver or a notebook type (clamshell type or folding type) personal computer, electronic devises according to the embodiments are not restricted to these. The electronic devices in the embodiments can be configured as an electronic device provided with a fan, more specifically, for example, a desktop or tablet (slate) type personal computer, a smart television, a video display device, a receiver, a video display controller, and a projector.

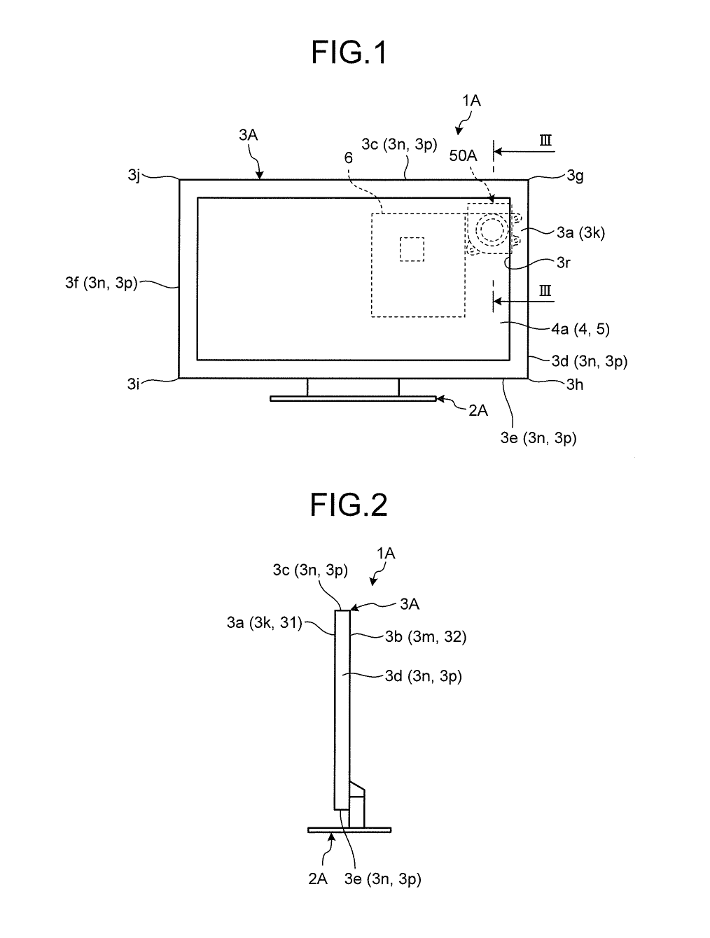

In a first embodiment, as illustrated in FIGS. 1 and 2 as one example, a television receiver 1A (an electronic device) comprises a supporting portion 2A and a housing 3A. Specifically, the housing 3A houses therein at least a portion of a display device 4. The supporting portion 2A (a stand portion, a pedestal portion, or a leg portion) supports the housing 3A. The supporting portion 2A can support the housing 3A to be movable (rotatable). Examples of the movement of the housing 3A in this case include tilting, pivoting, and swiveling.

The housing 3A, in the first embodiment, as illustrated in FIG. 1 as one example, is constructed in a quadrangular shape (in the first embodiment, a rectangular shape as one example) in a frontal view and in a back view. Furthermore, the housing 3A, in the first embodiment, as illustrated in FIG. 2 as one example, is constructed in a rectangular parallelepiped shape to be thin and flat in a front-back direction. The housing 3A comprises a surface 3a (an anterior surface, a top surface, a front face, or a surface portion), and on a side opposite the surface 3a, a surface 3b (a rear surface, a lower surface, a back surface, or a surface portion). Both the surface 3a and the surface 3b extend (expand) along a direction intersecting a thickness direction of the housing 3A (in the first embodiment, in an orthogonal direction as one example). The surface 3a and the surface 3b are nearly in parallel with each other. The housing 3A further comprises, as illustrated in FIG. 1, four ends 3c to 3f (sides, or edges) and four corners 3g to 3j (protruding portions, rounded portions, or ends) in a frontal view. The ends 3c and 3e are examples of longer sides. The ends 3d and 3f are examples of shorter sides.

The housing 3A further comprises, as one example, a wall 3k (a part, a plate, a frame, a front wall, a surface wall, or a top wall) having the surface 3a, and a wall 3m (a part, a plate, a rear wall, a back wall, or a bottom wall) having the surface 3b. The walls 3k and 3m are in a quadrangular shape (in the first embodiment, a rectangular shape as one example). The housing 3A further comprises four walls 3n (parts, plates, side walls, end walls, standing walls, or extending portions) having surfaces 3p (side surfaces, or circumferential surfaces) extending between the wall 3k and the wall 3m. On the wall 3k, an opening 3r in a quadrangular shape as one example is provided. Therefore, the wall 3k is in a quadrangular and frame-like shape.

Furthermore, the housing 3A can be constructed with a plurality of components (segmented bodies) combined. The housing 3A, in the first embodiment, as one example, comprises a housing member 31 (a front side member, a mask, a mask portion, a cover, a front cover, a cover portion, a portion, or an area) having at least the wall 3k, and a housing member 32 (a back side member, abase, abase portion, a bottom, a bottom portion, a cover, a rear cover, a cover portion, a portion, or an area) having at least the wall 3m. The walls 3n are comprised in at least one of the housing member 31 and the housing member 32 (for example, the housing member 32). Moreover, the housing 3A can comprise another housing member (an intermediate member, an isolating member, a barrier wall member, a wall member, an intervening member, a covering member, an inner plate, a middle plate, a middle frame, a shield, a portion, or an area, not illustrated) positioned between the housing member 31 and the housing member 32. The housing 3A can be composed of metallic or synthetic resin material. On the inner sides of the housing member 31 and the housing member 32 of the housing 3A, walls (projecting portions, or projecting walls, not illustrated) such as ribs can be provided. These walls facilitate an increase in the rigidity of the housing 3A.

In the first embodiment, on the surfaces 3a, 3b, and 3p of the housing 3A, as one example, connectors, operation modules, a camera module (a camera, or an imaging device), and others (not illustrated) can be provided. The connectors can be, for example, a connector for a power supply cable, a universal serial bus (USB) connector, a card connector, and connectors for earphones and a microphone. The operation modules can be, for example, a push button, a push switch, a slide switch, a pointing device, and a dial.

In the first embodiment, as illustrated in FIG. 1 as one example, a display screen 4a of the display device 4 (a display module, a display, or a panel) positioned on the surface 3a side is visible from the front (outside) of the housing 3A through the opening 3r. The display device 4 is configured in a quadrangular shape (in the first embodiment, a rectangular shape as one example) in a frontal view. The display device 4 is further configured in a rectangular parallelepiped shape to be thin and flat in the front-back direction. The display device 4, for example, is a liquid crystal display (LCD) or an organic electro-luminescent display (OELD).

In the first embodiment, on the front side (a face side, or the wall 3k side) of the display device 4, as one example, a touch panel 5 (as one example, an input operation panel, a touch sensor, an operation surface, or a cover) can be provided. In this case, the touch panel 5 is configured in a transparent and relatively thin quadrangular shape, covering the display screen 4a. A user, for example, can execute input process by performing an operation of touching, pressing, or rubbing the touch panel 5 with a finger or a component (for example, a stylus, not illustrated), or moving the finger or the stylus near the touch panel 5. The light emitted from the display screen 4a of the display device 4 passes through the touch panel 5 and goes out ahead (outside) of the housing 3A through the opening 3r of the wall 3k.

In the first embodiment, as one example, one or more substrates 6 (a circuit board, a control board, a main board, electrical components, or components) are housed on the rear side (a reverse side, aback side, the wall 3m side, or the side opposite the display screen 4a) of the display device 4 inside the housing 3A. The substrates 6 are provided roughly in parallel with the display device 4. The substrates 6 are provided in a condition to be away from the walls 3k, 3m, 3n, and others, in other words, in a condition where spaces (gaps) are formed with the walls 3k, 3m, 3n, and others.

In the first embodiment, on the substrates 6, as one example, a plurality of components (not illustrated), for example, a central processing unit (CPU), a graphics controller, power supply circuit components, a platform controller hub (PCH), a memory slot connector, an LCD connector, an input/output (I/O) connector, a power coil, elements, and connectors can be mounted. Furthermore, the control circuit can comprise, for example, a video signal processing circuit, a tuner, a High-Definition Multimedia Interface (HDMI) signal processor, an audio video (A/V) input terminal, a remote control signal receiver, a controller, a selector, an on-screen display interface, a storage module (for example, a read only memory (ROM), a random access memory (RAM), a hard disk drive (HDD), and a solid state drive (SSD)), and an audio signal processing circuit. The control circuit controls such as the output of videos (such as movies or still pictures) on the display screen 4a of the display device 4, the output of audio from a speaker (not illustrated), and light emission of a light emitting diode (LED, not illustrated). The display device 4, the speaker, and the LED are examples of output modules.

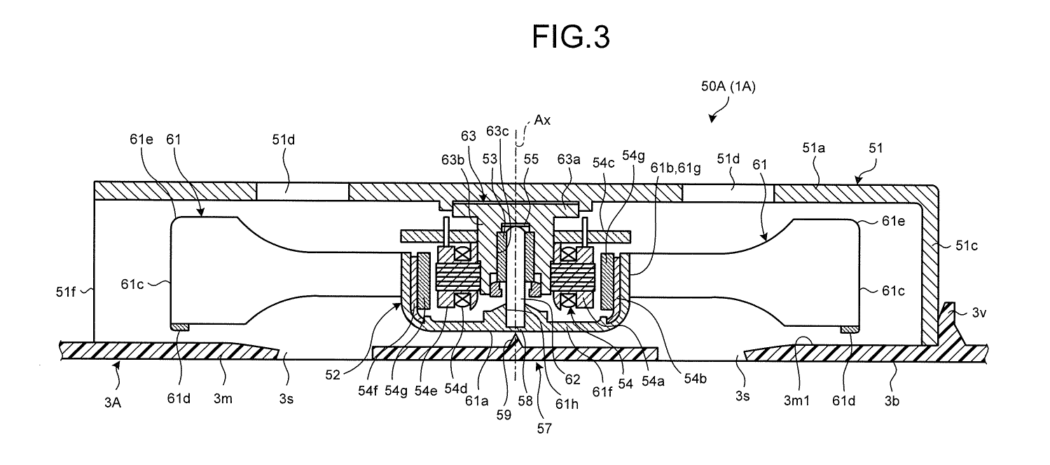

In the first embodiment, as illustrated in FIGS. 1 and 3 as one example, a fan unit 50A is provided. The fan unit 50A (an air-cooling device, a cooling device), by rotating a fan 61, takes air in and exhausts the air out. By an airflow formed by the rotation of the fan 61, heating bodies (components, electronic components, electrical components, or heating modules), heat exchangers of cooling devices (heat exchanging units, or heat dissipating fins), and others inside the housing 3A are cooled.

In the first embodiment, as illustrated in FIG. 3 as one example, the fan unit 50A is attached on a surface 3m1 (an inner surface, or a surface inside the housing) on a side opposite the surface 3b with respect to the wall 3m (an outer wall, a top wall, a bottom wall, or a first wall) of the housing 3A. In the first embodiment, as one example, the fan unit 50A is opened to one side in an axis direction thereof, and does not have a wall on one side in the axis direction. In other words, the wall 3m is configured as a part of the case (housing) of the fan unit 50A (a wall on one side in an axis direction of a rotation axis Ax). The wall 3m covers the outer side (one side in the axis direction, a side opposite the display device 4, a side opposite the display screen 4a, or the surface 3b (rear surface) side) of the housing of the fan 61. On the wall 3m, ventilation holes 3s are provided.

More specifically, in the first embodiment, as one example, a wall 51a (an inner wall, a top wall, a bottom wall, a second wall, or a case) and a wall 51c (a side wall, a circumferential wall, an extending portion, a third wall, or a case) are integrated to configure a case component 51 (a component). In the first embodiment, the case component 51 is, as illustrated in FIG. 5 as one example, attached on the surface 3m1 of the wall 3m by binding tools 30 (fixing tools, for example, screws).

The wall 51a is provided on a side opposite the wall 3m with respect to the fan 61 (on other side in the axis direction of the rotation axis Ax, or an inner side of the housing) to extend (expand) along a direction intersecting the rotation axis Ax (an orthogonal direction). More specifically, the wall 51a covers the inner side of the housing of the fan 61 (on other side in the axis direction, on the display device 4 side, on the display screen 4a side, or on the surface 3a (front surface) side). The wall 51a is roughly in parallel with the wall 3m. On the wall 51a, ventilation holes 51d are provided. The wall 51c extends between the wall 3m and the wall 51a. On the wall 51c, a ventilation hole 51f is provided. The ventilation hole 51f is provided on one side of the fan 61 in a radial direction (in the first embodiment, on an upper side in FIG. 1 as one example). In other words, the wall 51c covers the outer side of the fan 61 in the radial direction at the portion other than the portion at which the ventilation hole 51f is provided.

The ventilation holes 3s and 51d overlap with the fan 61 in a thickness direction of the fan unit 50A (an axis direction of the rotation axis Ax, a thickness direction of the housing 3A, or an overlapping direction (a facing direction) of the wall 3m and the wall 51a). The ventilation hole 51f overlaps with the fan 61 in a direction orthogonal to the thickness direction of the fan unit 50A (a radial direction of the rotation axis Ax, a direction along the surface 3m1). The airflow characteristics (such as the direction, flow rate, and flow velocity) of the fan unit 50A can be changed appropriately according to the specifications of the case (the case component 51 and the wall 3m) and the fan 61 (such as the structure, shape, number of rotations, and rotating direction).

A rotating body 52 (a rotating portion, a moving portion, or a rotor), as illustrated in FIG. 3, comprises the fan 61 and a shaft 62 (a shaft portion, or a column portion). The rotating body 52 is housed in the case component 51. The rotating body 52 rotates around the shaft 62. In other words, the shaft 62 extends along the thickness direction of the fan unit 50A.

The fan 61 comprises a base 61a to which one end of the shaft 62 is fixed, and a plurality of blades 61c extending from a circumferential surface 61b of the base 61a. The fan 61 is composed of, for example, synthetic resin or metallic material. The base 61a is formed in a cylindrical and cup-like shape, and is arranged at a position at which its opening faces the wall 51a. The base 61a comprises a base wall 61f in a disc shape, and a side wall 61g extending from the circumferential edge of the base wall 61f towards the wall 51a. The outer circumferential surface of the side wall 61g is the circumferential surface 61b of the base 61a. On the inner surface of the base wall 61f, a shaft fixing portion 61h in a recessed form is provided, and the one end of the shaft 62 is inserted and fixed to the shaft fixing portion 61h.

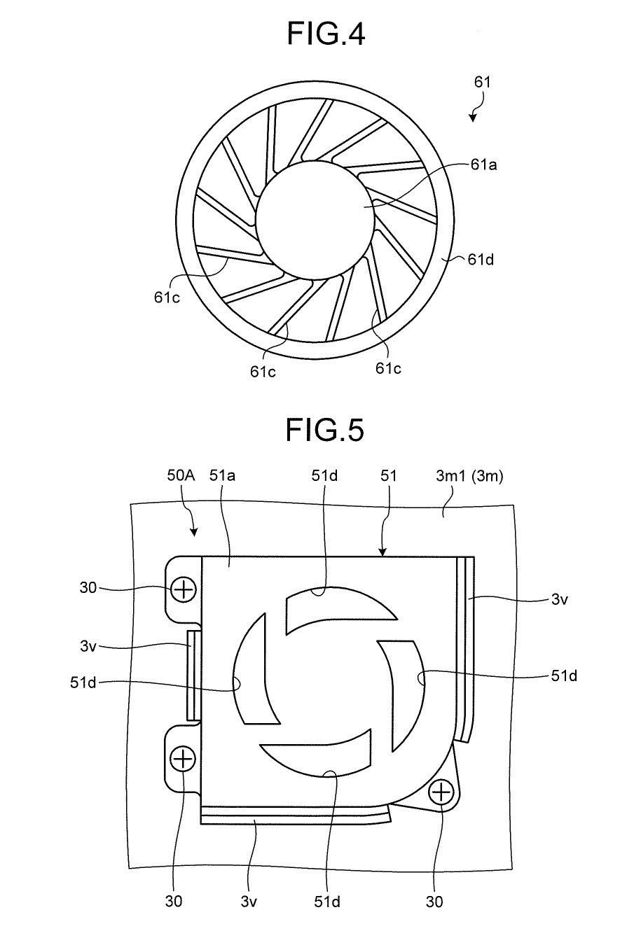

The fan 61, as illustrated in FIG. 4, further comprises an annular connecting member 61d on the outer circumferential portion thereof. The connecting member 61d connects outer edges of the blades 61c on the axis direction side. Furthermore, as illustrated in FIG. 3, the ends 61e of the blades 61c are formed in a curved (inclined) manner.

A shaft bearing 53 is provided on a base component 63 that is fixed to the case component 51, and supports the shaft 62 in a rotatable manner. The base component 63 is fixed (attached) to the case component 51 by, for example, adhesion or screwing. The base component 63 can be integrally formed with the case component 51. The shaft bearing 53 is formed in a hollow cylindrical shape. The shaft bearing 53 can be configured as, for example, a needle bearing, a ball bearing, a slide bearing, a liquid bearing, and an oil retaining bearing. The shaft bearing 53 is fixed to a base 63a of the base component 63 being fitted to an opening 63c formed in a cylinder of a cylindrical portion 63b that is provided in a standing manner on the base 63a of the base component 63. At the bottom surface of the cylindrical portion 63b, a thrust plate 55 is fixed. The thrust plate 55 supports the end face of the shaft 62 in the axis direction. The opening 63c of the shaft bearing 53 provided on the base 63a accommodates at least a portion of the shaft 62. In the first embodiment, as one example, the cylindrical portion 63b, the shaft bearing 53, and the thrust plate 55 are examples of a rotary supporting portion that rotatably supports the rotating body 52 as a rotating portion.

A motor 54 comprises, as illustrated in FIG. 3, a stator 54a, a rotor 54b surrounding the stator 54a, and a circuit substrate 54c. The stator 54a comprises an iron core 54e to which a winding wire 54d is mounted. The rotor 54b comprises a cylindrical yoke 54f, and a plurality of magnets 54g fixed to the inner circumferential surface of the yoke 54f being spaced apart from one another along the circumferential direction. The yoke 54f is fixed to the side wall 61g of the base 61a on the inner circumferential side. The circuit substrate 54c is connected with lead wires (not illustrated), and the circuit substrate 54c transmits the power supplied from the lead wires to the winding wire 54d. In the motor 54, by the electromagnetic action between the magnets 54g and the stator 54a facing the magnets 54g, the rotor 54b rotates, and thus the rotating body 52 rotates.

In the first embodiment, as one example, in the portion at which the fan unit 50A is provided, a supporting structure 57 lies between the wall 51a and the wall 3m at the portion at which the rotation axis Ax of the rotating body 52 (the fan 61) is positioned. In the first embodiment, as one example, the supporting structure 57 comprises the cylindrical portion 63b, the thrust plate 55, the shaft bearing 53, the shaft 62, the base wall 61f, and a protruding portion 59 (a projecting portion, or a contacting portion). In the first embodiment, because the supporting structure 57 lies between the wall 51a and the wall 3m, even when an external force is acting on the wall 3m towards inside the housing, deforming of the wall 3m is suppressed. Consequently, as one example, at the portion at which the fan unit 50A is provided, the wall 3m can be made thinner, thereby contributing to weight saving of the housing 3A, as one example.

Furthermore, in the first embodiment, as one example, the protruding portion 59 (a projecting portion, or a contacting portion) faces the base wall 61f (the rotating body 52) at the position of the rotation axis Ax (center of rotation). Accordingly, when the wall 3m is deformed by such as being pressed towards inside the housing, the protruding portion 59 contacts the rotating body 52 at the position of the rotation axis Ax (a rotation center portion 58). Therefore, as compared with when contacting a position away from the rotation axis Ax, a moment arm is smaller, and thus a resistance torque of rotation for the rotating body 52 caused by the contact (abutment) of the protruding portion 59 becomes smaller. As a result, in accordance with the first embodiment, as one example, the rotation of the rotating body 52 is not likely to stop.

In the first embodiment, as one example, the protruding portion 59 and the wall 3m collectively serve as a suppressing portion (a movement regulating portion, a retaining portion, or a retaining structure) that prevents the rotating body 52 from coming off the shaft bearing 53 (the fan unit 50A, or a rotary supporting portion). There is magnetic force (attracting force) acting on between the stator 54a and the magnets 54g, and by the magnetic force, the rotating body 52 is prevented from coming off (separating from) the shaft bearing 53. However, when an external force, an inertial force, or the like is exerted to the fan unit 50A, there may be a situation where the force in a direction to break away from the shaft bearing 53 is acting on the rotating body 52 opposing the magnetic force. Even in such a situation, in the first embodiment, as one example, the wall 3m and the protruding portion 59 can prevent the rotating body 52 from coming off the shaft bearing 53.

In the first embodiment, as illustrated in FIGS. 3 and 5 as one example, wall 3v (cover) that cover a portion (end portions on projecting side) of the wall 51c project out from the wall 3m of the housing 3A. The wall 3v cover gaps between the wall 51c and the wall 3m. Therefore, in accordance with the first embodiment, as one example, leakage of the air from the gaps is suppressed. Accordingly, as one example, deterioration of operating efficiency, and eventually deterioration of cooling efficiency in the operation of the fan unit 50A (rotation of the fan 61) are suppressed. The wall 3v further serve as positioning portions (guides) when mounting the case component 51 (the fan unit 50A) on the housing 3A. This means that the side wall (a third wall) of the fan unit 50A is constructed by the wall 51c of the case component 51 and the wall 3v of the housing 3A being overlapped in the axis direction of the rotation axis Ax. A portion in which the walls 51c and 3v are overlapped tends to have a larger air resistance, and thus the air is harder to leak out.

As described in the foregoing, in the first embodiment, as one example, the supporting structure 57 lies between the wall 51a and the wall 3m at the portion at which the rotation axis Ax of the rotating body 52 (the fan 61) is positioned. Therefore, in accordance with the first embodiment, as one example, even when the rigidity of the wall 51a or the wall 3m is lower, deformation of the walls 51a and 3m is more likely to be suppressed.

Furthermore, in the first embodiment, as one example, the wall 3m has the protruding portion 59 that contacts the rotation center portion 58 of the rotating body 52 when the wall 3m is deformed. Consequently, in accordance with the first embodiment, as one example, as compared with when the wall 3m contacts the rotating body 52 at a position further away (farther) from the rotation axis Ax, the resistance torque that opposes the rotation of the rotating body 52 caused by the contact of the wall 3m and the rotating body 52 is smaller.

Moreover, in the first embodiment, as one example, the supporting structure 57 is positioned closer to the rotation axis Ax than the wall 51c. Consequently, as one example, as compared with when the supporting structure 57 is positioned further outside than the wall 51c, deformation of the walls 3k and 3m is more likely to be suppressed.

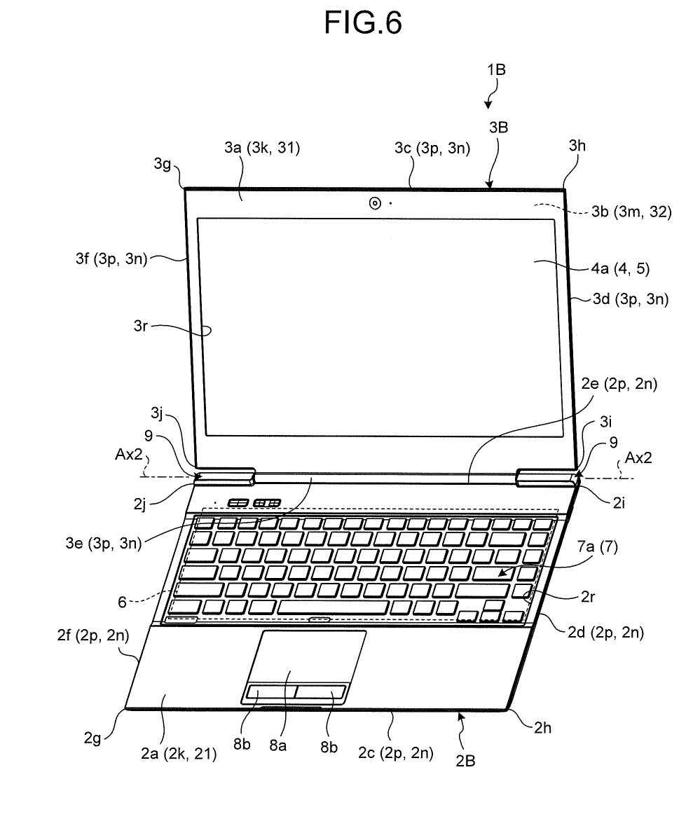

In a second embodiment, as illustrated in FIG. 6 as one example, an electronic device 1B comprises a first housing 3B, and a second housing 2B. Specifically, the first housing 3B (a first portion, or a housing) houses therein at least a portion of the display device 4. On the first housing 3B, the transparent touch panel 5 (a touch sensor, an input operation module, an input receiver, or an input module) can be further provided overlapping the display device 4. The user, for example, can view videos (images) displayed on the display screen 4a of the display device 4 through the touch panel 5.

As illustrated in FIG. 6, the second housing 2B (a second portion, or a housing) houses therein the substrates 6. On the second housing 2B, a keyboard 7 (an input operation module, a first input operation module, an input receiver, or an input module), a pointing device 8a (an input operation module, a second input operation module, an input receiver, and an input module), click buttons 8b (input operation modules, input receivers, or input modules), and such are provided.

The first housing 3B and the second housing 2B are rotatably connected by a hinge mechanism 9 (a hinge, a connector, a coupling portion, a rotatably supporting portion, a connecting mechanism, a coupling mechanism, or a rotatably supporting mechanism). The first housing 3B and the second housing 2B are connected by the hinge mechanism 9 to be rotatable at least between an opened state illustrated in FIG. 6 and a folded state not illustrated. In the second embodiment, as one example, the hinge mechanism 9 connects the first housing 3B and the second housing 2B to be rotatable around a rotation axis Ax2.

The display screen 4a of the display device 4 is visible through an opening 3r provided on a surface 3a (an anterior surface, a top surface, a front face, or a face portion) of the first housing 3B. The keyboard 7, the pointing device 8a, the click buttons 8b, and such are exposed on a surface 2a (an anterior surface, a top surface, a front face, or a face portion) of the second housing 2B. In the folded state, the surface 3a of the first housing 3B and the surface 2a of the second housing 2B overlap with each other, and the display screen 4a, the keyboard 7, the pointing device 8a, the click buttons 8b, and others are hidden by the first housing 3B and the second housing 2B. In the opened state, the surface 3a of the first housing 3B and the surface 2a of the second housing 2B are exposed, and the display screen 4a, the keyboard 7, the pointing device 8a, the click buttons 8b, and others are available for use (become visible or operational). There may be a situation where one side of the first housing in a thickness direction is covered with a surface of a touch panel. In this case, the surface of the touch panel is the surface of the first housing. Furthermore, there may be a situation where a display device with a touch panel (not illustrated) is provided on the second housing, in place of the keyboard. Moreover, there may be a situation where one side of the second housing in a thickness direction is covered with a surface of a touch panel. In these cases, the surface of the touch panel is the surface of the second housing.

The first housing 3B, in the second embodiment, as illustrated in FIG. 6 as one example, is configured in a quadrangular shape (in the second embodiment, a rectangular shape as one example) in a frontal view and in a back view. Furthermore, the first housing 3B, in the second embodiment, as one example, is configured in a thin and flat rectangular parallelepiped shape. The first housing 3B comprises the surface 3a and a surface 3b (a rear surface, a lower surface, a back surface, or a surface portion) on the side opposite the surface 3a. The surface 3a and the surface 3b are roughly in parallel with each other. The first housing 3B, as illustrated in FIG. 6, further comprises four ends 3c to 3f (sides, or edges) and four corners 3g to 3j (protruding portions, rounded portions, or ends) in a frontal view. The ends 3c and 3e are examples of longer sides. The ends 3d and 3f are examples of shorter sides.

The first housing 3B further comprises a wall 3k (a portion, a plate, a frame, a front wall, a surface wall, or a top wall) having the surface 3a, and a wall 3m (a portion, a plate, a rear wall, a back wall, or a bottom wall) having the surface 3b. The walls 3k and 3m are in a quadrangular shape (in the second embodiment, a rectangular shape as one example). The first housing 3B further comprises four walls 3n (portions, plates, side walls, end walls, standing walls, or extending portions) having surfaces 3p (side surfaces, or circumferential surfaces) extending between the wall 3k and the wall 3m. On the wall 3k, the opening 3r in a quadrangular shape as one example is provided. Therefore, the wall 3k is in a quadrangular and frame-like shape.

Furthermore, the first housing 3B can be constructed with a plurality of components (segmented bodies) combined. The first housing 3B comprises, in the first embodiment, as one example, a housing member 31 (a front side member, a mask, a mask portion, a cover, a front cover, a cover portion, a portion, or an area) having at least the wall 3k, and a housing member 32 (a back side member, a base, a base portion, a bottom, a bottom portion, a cover, a rear cover, a cover portion, a portion, or an area) having at least the wall 3m. The walls 3n are comprised in at least one of the housing member 31 and the housing member 32 (for example, the housing member 32). Moreover, the first housing 3B can comprise another housing member (an intermediate member, an isolating member, a barrier wall member, a wall member, an intervening member, a covering member, an inner plate, a middle plate, a middle frame, a shield, a portion, or an area, not illustrated) positioned between the housing member 31 and the housing member 32. The first housing 3B can be composed of, for example, metallic or synthetic resin material.

In the second embodiment, as one example, the display device 4 is configured in a quadrangular shape (in the second embodiment, a rectangular shape as one example) in a frontal view. Furthermore, the display device 4 is configured in a rectangular parallelepiped shape being thin and flat in a front-back direction. The display device 4, for example, is a liquid crystal display (LCD) or an organic electro-luminescent display (GELD).

In the second embodiment, as one example, the touch panel 5 is configured to be transparent in a relatively thin quadrangular shape. An operator (for example, a user) can execute input process by performing an operation of touching, pressing, or rubbing the touch panel 5 with a finger or a component (for example, a stylus, not illustrated), or moving the finger or the stylus near the touch panel 5. The light emitted from the display screen 4a of the display device 4 passes (transmits) through the touch panel 5 and goes out ahead (outside) of the first housing 3B through the opening 3r of the wall 3k.

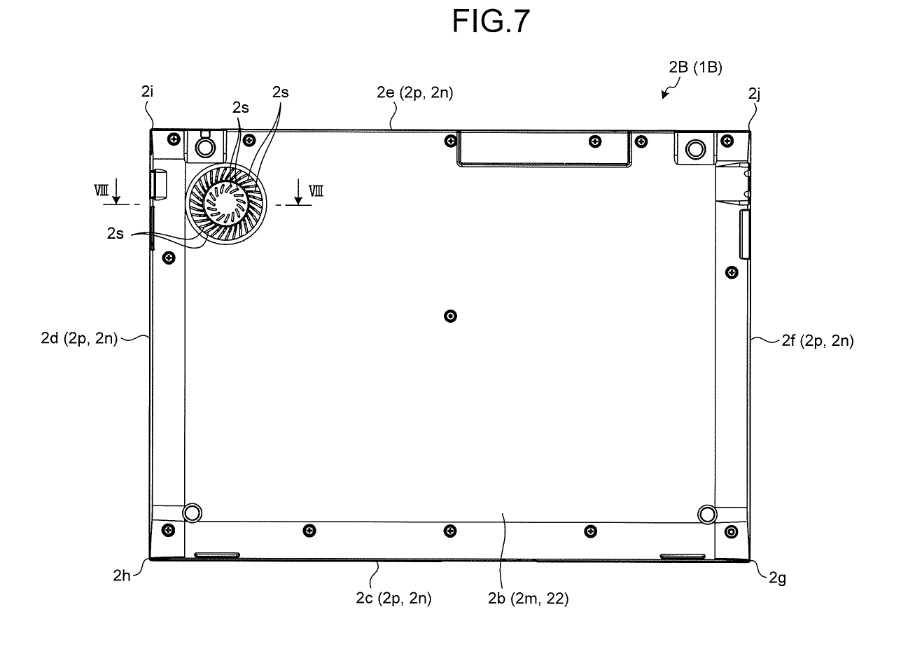

The second housing 2B, in the second embodiment, as illustrated in FIGS. 6 and 7 as one example, is configured in a quadrangular shape (in the second embodiment, a rectangular shape as one example) in a frontal view and in a back view. The second housing 2B, in the second embodiment, as one example, is configured in a thin and flat rectangular parallelepiped shape. The second housing 2B comprises the surface 2a and a surface 2b (a rear surface, a lower surface, a back surface, or a surface portion) on the side opposite the surface 2a. The surface 2a and the surface 2b are roughly in parallel with each other. The second housing 2B further comprises four ends 2c to 2f (sides, or edges) and four corners 2g to 2j (protruding portions, rounded portions, or ends) in a frontal view with respect to the surface 2a. The ends 2c and 2e are examples of longer sides. The ends 2d and 2f are example of shorter sides.

The second housing 2B further comprises a wall 2k (a portion, a plate, a frame, a front wall, a surface wall, or a top wall) having the surface 2a, and a wall 2m (a portion, a plate, a rear wall, a back wall, or a bottom wall) having the surface 2b. The walls 2k and 2m are in a quadrangular shape (in the second embodiment, a rectangular shape as one example). The second housing 2B further comprises four walls 2n (portions, plates, side walls, end walls, standing walls, or extending portions) having surfaces 2p (side surfaces, or circumferential surfaces) extending between the wall 2k and the wall 2m. On the wall 2k, an opening 2r in a quadrangular shape as one example is provided. Accordingly, the wall 2k is in a quadrangular and frame-like shape.

Furthermore, the second housing 2B, as one example, can be configured with a plurality of components (segmented bodies) combined. The second housing 28, in the second embodiment, as one example, comprises a housing member 21 (a front side member, a mask, a mask portion, a cover, a front cover, a cover portion, a portion, or an area) having at least the wall 2k, and a housing member 22 (a back side member, a base, a base portion, a bottom, a bottom portion, a cover, a rear cover, a cover portion, a portion, or an area) having at least the wall 2m. The walls 2n are comprised in at least one of the housing member 21 and the housing member 22 (for example, the housing member 22). Moreover, the second housing 2B can comprise another housing member (an intermediate member, an isolating member, a barrier wall member, a wall member, an intervening member, a covering member, an inner plate, a middle plate, a middle frame, a shield, a portion, or an area, not illustrated) positioned between the housing member 21 and the housing member 22. The second housing 2B can be composed of, for example, metallic or synthetic resin material.

In the second embodiment, as one example, an operation surface 7a (a surface, or a top surface) of the keyboard 7 is exposed towards the front (outside) of the second housing 2B through the opening 2r. On the surface 2a, the keyboard 7 is positioned close to the end 2e side, and the pointing device 8a and the click buttons 8b are arranged close to the end 2c side that is on the side opposite to the end 2e. The end 2e is positioned on the back side in a depth direction (a front-back direction), and the end 2c is positioned on the near side.

In the second embodiment, as illustrated in FIG. 6 as one example, the second housing 2B houses one or more substrates 6 (a circuit board, a control board, a main board, or electrical components) on the rear side of the keyboard 7 (a reverse side, a back side, the wall 2m side, or the side opposite the operation surface 7a). The substrates 6 are provided in parallel with the keyboard 7. The substrates 6 are provided in a condition to be away from the walls 2k, 2m, 2n, and others, in other words, in a condition where spaces (gaps) are formed with the walls 2k, 2m, 2n, and others.

In the second embodiment, as one example, on the substrates 6, a plurality of components (not illustrated) such as a central processing unit (CPU), a graphics controller, power supply circuit components, a platform controller hub (PCH), a memory slot connector, an LCD connector, an input/output (I/O) connector, a power coil, elements, and connectors can be mounted. The control circuit can comprise, for example, a video signal processing circuit, a tuner, a High-Definition Multimedia Interface (HDMI) signal processor, an audio video (A/V) input terminal, a remote control signal receiver, a controller, a selector, an on-screen display interface, a storage module (for example, a read only memory (ROM), a random access memory (RAM), a hard disk drive (HDD), and a solid state drive (SSD)), and an audio signal processing circuit. The control circuit controls such as the output of videos (such as movies and still pictures) on the display screen 4a of the display device 4, the output of audio from a speaker (not illustrated), and light emission of a light emitting diode (LED, not illustrated). The display device 4, the speaker, and the LED are examples of output modules.

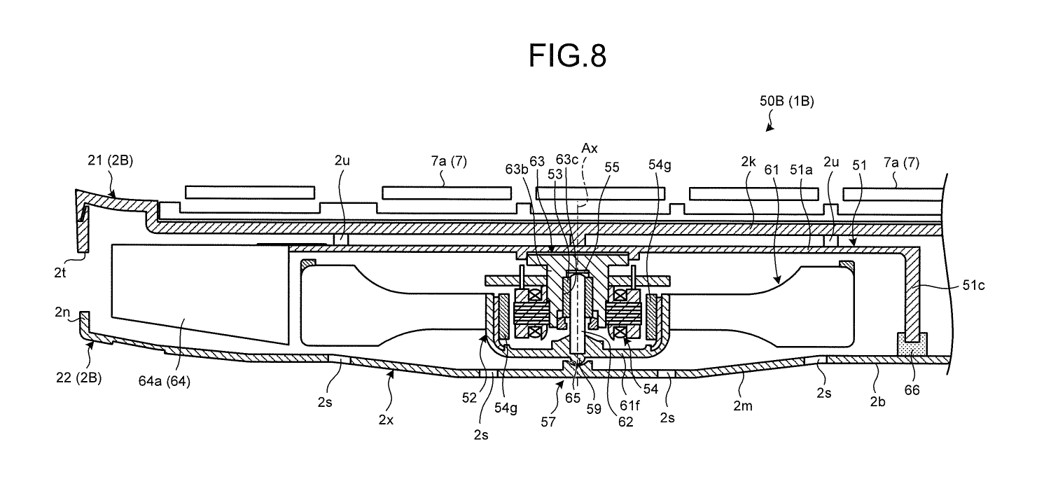

In the second embodiment, as illustrated in FIG. 7 as one example, the wall 2m (a first wall) has a plurality of ventilation holes 2s opened in a slit-like manner and arranged radially in a circle form. A fan unit 50B (see FIG. 8) is provided inside the second housing 2B at a position overlapping the ventilation holes 2s in the thickness direction of the second housing 2B, more specifically, near a corner 2i and the ends 2d and 2e.

As it becomes apparent when FIG. 8 is compared with FIG. 3, the structure of the fan unit 50B in the second embodiment is similar to that of the fan unit 50A in the first embodiment. Accordingly, the second embodiment can yield similar results (effects) based on a similar structure to that in the first embodiment. By the rotation of the fan 61, the air taken inside the housing from the ventilation holes 2s exchanges heat with fins 64a (heat dissipating fins, a heat exchanging unit, or a heat exchanger) of a cooling device 64 to cool the fins 64a, and is exhausted to the outside of the housing from ventilation holes 2t in the walls 2n.

In the second embodiment, as illustrated in FIG. 8 as one example, the wall 2k of the second housing 2B has a plurality of protruding portions 2u (projecting portions, intervening portions, or supporting portions) projecting towards the walls 51a and 51c of the case component 51 (towards inside the housing). At least one of the protruding portions 2u is positioned at an extension of the rotation axis Ax in a state overlapping the shaft 62 (the supporting structure 57) in the thickness direction of the second housing 2B. The other protruding portions 2u are provided at positions overlapping the wall 51c in the thickness direction of the second housing 2B. Accordingly, a force (load) acting upon one of the wall 2k and the wall 2m of the second housing 2B towards the other side is transmitted to the other via the supporting structure 57 and the protruding portions 2u. Therefore, in accordance with the second embodiment, as one example, the fan unit 50B can contribute to an improvement in rigidity of the second housing 2B. Consequently, in accordance with the second embodiment, as one example, even when the rigidity of the wall 2k or the wall 2m is lower, deformation of the walls 2k and 2m is more likely to be suppressed. Therefore, in accordance with the second embodiment, as one example, the walls 2k and 2m are likely to be configured thinner, and eventually the second housing 2B is likely to be constructed lighter in weight. Furthermore, in accordance with the second embodiment, as one example, the protruding portion 2u provided corresponding to the central portion of the fan unit 50B can serve as a portion of the supporting structure 57 that lies in the thickness direction of the second housing 2B between the wall 2k and the wall 2m of the second housing 2B. The protruding portions 2u are separated from the wall 51a of the case component 51 when the walls 2k and 2m are in a free state. When a force (load) is acting on at least one of the walls 2k and 2m towards the inside of the housing, the protruding portions 2u contact (abut with) the wall 51a and lie between the wall 2k and the wall 51a. The protruding portions 2u can be provided not on the wall 2k but on the wall 51a, or can be provided on both the wall 2k and the wall 51a. Furthermore, flexible members (elastic members, or buffering members, for example, expandable members and elastomer) can be provided between the protruding portions 2u and the wall 51a (or the wall 2k).

In the second embodiment, as illustrated in FIG. 8 as one example, the protruding portion 59 is provided on the base wall 61f of the rotating body 52. Corresponding to (facing) the protruding portion 59, the wall 2m of the second housing 2B has an accommodating portion 65 (a recessed portion) that accommodates the protruding portion 59 in a rotatable manner. The protruding portion 59 has a roughly spherical outer surface, and the accommodating portion 65 has a roughly spherical (basin-like) inner surface. The curvature radius of the inner surface of the accommodating portion 65 is larger than that of the outer surface of the protruding portion 59. In the accommodating portion 65 (between the protruding portion 59 and the accommodating portion 65), a lubricant (for example, grease or oil, not illustrated) may be provided. The protruding portion 59 can be provided not on the rotating body 52 but on the wall 2m, and the accommodating portion 65 can be provided not on the wall 2m but on the rotating body 52. As in the foregoing, in the second embodiment, as one example, the accommodating portion 65 that accommodates the protruding portion 59 is provided. Consequently, in accordance with the second embodiment, as one example, wear is likely to be suppressed in the protruding portion 59 or the portion at which the protruding portion 59 contacts (in the second embodiment, the wall 2m as one example). Furthermore, in the second embodiment, as one example, a lubricant can be provided between the protruding portion 59 and the accommodating portion 65. As a result, in accordance with the second embodiment, as one example, wear is further more likely to be suppressed in the protruding portion 59 or the portion at which the protruding portion 59 contacts.

In the second embodiment, as illustrated in FIG. 8 as one example, an elastic member 66 (a flexible member, a sealing member, a covering member, or a covering portion) is provided between the wall 51c and the wall 2m (first wall). The elastic member 66, as one example, is constructed with a member having flexibility and elasticity such as synthetic resin material (for example, expandable resin material or sponge) and elastomer (for example, synthetic rubber). The elastic member 66 covers the gap between the wall 51c and the wall 2m, thereby sealing the gap. Accordingly, leakage of the air from the gap is suppressed. Consequently, as one example, deterioration of operating efficiency, and eventually deterioration of cooling efficiency in the operation of the fan unit 50B (rotation of the fan 61) are suppressed. Furthermore, because the elastic member 66 has flexibility or elasticity, even when a positional deviation with respect to the wall 51c arises, the gap with the wall 51c can be sealed. In addition, the elasticity facilitates an increase in the contact pressure of the contacting portion, thereby facilitating an increase in the seal performance.

In the second embodiment, as illustrated in FIG. 8 as one example, the portion of the wall 2m overlapping the fan unit SOB bulges out (being inflected or curved) towards the outside of the second housing 2B, whereby a bulging portion 2x (a projecting portion) is provided to increase the rigidity. Additionally, ventilation holes can be provided in the wall 51a.

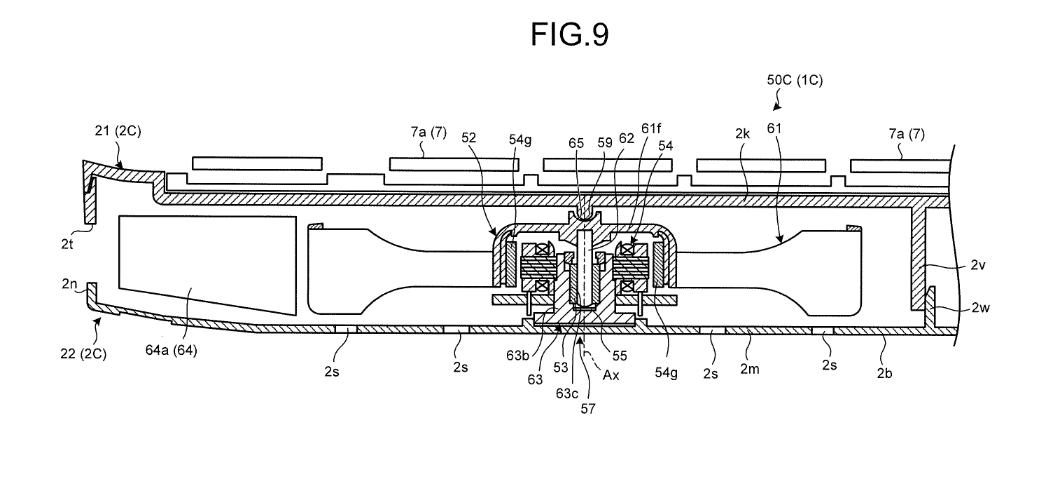

As it becomes apparent when FIG. 9 is compared with FIG. 8, the structure of a fan unit 50C housed in a second housing 2C of an electronic device 1C according to a third embodiment is similar to that of the fan unit 50B in the second embodiment. Consequently, the third embodiment can yield similar results (effects) based on a similar structure to that in the second embodiment.

In the third embodiment, as illustrated in FIG. 9 as one example, the fan unit 50C is attached not to the wall 2k but to the wall 2m. Furthermore, the protruding portion 59 is provided on the wall 2k and the accommodating portion 65 is provided on the rotating body 52. This structure can yield similar results as in the second embodiment.

In the third embodiment, as illustrated in FIG. 9 as one example, the fan unit 50C does not have a case component, but is surrounded by the walls 2k, 2m, 2v, and 2w of the second housing 2C. More specifically, the case component of the fan unit 50C is configured by the second housing 2C. The wall 2v projects from the wall 2k towards the wall 2m, and is provided in a state surrounding the fan 61 from the outside (outer circumferential side, or side opposite to the rotation axis Ax) with some space therebetween. The wall 2w projects from the wall 2m towards the wall 2k, and is provided in a state surrounding the fan 61 from the outside with some space therebetween. The wall 2w is further in contact with the outer circumferential side of the wall 2v. When assembling the housing member 21 and the housing member 22 of the second housing 2C, the wall 2w guides the wall 2v and the wall 2v guides the wall 2w. Furthermore, because the walls 2w and 2v overlap with each other, leakage of the air is likely to be suppressed from the portion in which the walls 2w and 2v are overlapped with each other. Consequently, in accordance with the third embodiment, as one example, the structure of the second housing 2C is likely to be simplified as the case component can be omitted, and eventually, as one example, the second housing 2C is likely to be made much thinner or lighter in weight.

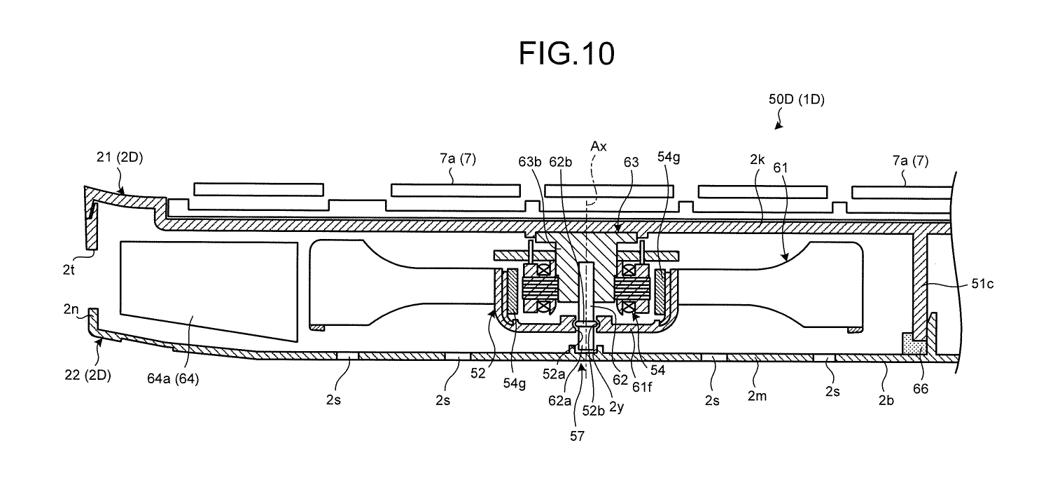

As it becomes apparent when FIG. 10 is compared with FIGS. 8 and 9, a fan unit 50D housed in a second housing 2D of an electronic device 1D according to a fourth embodiment has a similar structure to the fan unit 50B in the second embodiment and the fan unit 50C in the third embodiment. Accordingly, the fourth embodiment can yield similar results (effects) based on a similar structure to those in the second embodiment and in the third embodiment.

In the fourth embodiment, as illustrated in FIG. 10 as one example, the fan unit 50D is attached not to the wall 2m but to the wall 2k. This structure can yield similar results to those with the fan unit 50D provided on the wall 2m.

In the fourth embodiment, as one example, the shaft 62 (a second projecting portion) is fixed to the base component 63 (on the wall 2k side) and penetrates through the base wall 61f of the rotating body 52. An end 62a of the shaft 62 on the wall 2m side faces a recessed portion 2y provided on the wall 2m. At least in a state where the shaft 62 and the wall 2m come close to each other by deformation and such of at least the walls 2k and 2m, the end 62a is accommodated in the recessed portion 2y and contacts (abuts with) the bottom portion (the wall 2m) of the recessed portion 2y. In other words, in the fourth embodiment, as one example, the supporting structure 57 comprises the base component 63 and the shaft 62. The fourth embodiment can yield similar results to those in the above-described embodiments due to the supporting structure 57 because the supporting structure 57 lies between the wall 2k and the wall 2m. The irregular structure by the shaft 62 and the recessed portion 2y contributes to the positioning between the shaft 62 and the wall 2m. The recessed portion may be provided on the shaft 62 and the projecting portion may be provided on the wall 2m. Furthermore, the shaft 62 may be fixed on the wall 2m side.

In the fourth embodiment, as one example, the rotating body 52 is rotatably supported by a portion of the supporting structure 57 (in the fourth embodiment, the shaft 62 as one example). The rotating body 52 has an opening 52a (a through hole) through which the shaft 62 penetrates, and the opening 52a has a groove 52b that accommodates a swelled portion 62b (a projecting portion) provided on the outer circumference of the shaft 62. In the fourth embodiment, as one example, the swelled portion 62b and the groove 52b (a peripheral portion thereof) collectively serve as a suppressing portion (a movement regulating portion, a retaining portion, or a retaining structure) that prevents the rotating body 52 from coming off the shaft 62. Furthermore, in the fourth embodiment, as one example, the swelled portion 62b serves as a rotary supporting portion that supports the rotating body 52 in a rotatable manner. In the fourth embodiment, as one example, this structure simplifies the supporting structure 57 and the rotary supporting structure of the rotating body 52 even further. The groove portion may be provided on the shaft 62, and the swelled portion may be provided on the rotating body 52. Furthermore, when integrating the rotating body 52 and the shaft 62, at least one of the rotating body 52 and the shaft 62 involves elastic deformation. Additionally, a lubricant (grease and such) may be provided between the swelled portion 62b and the groove 52b.

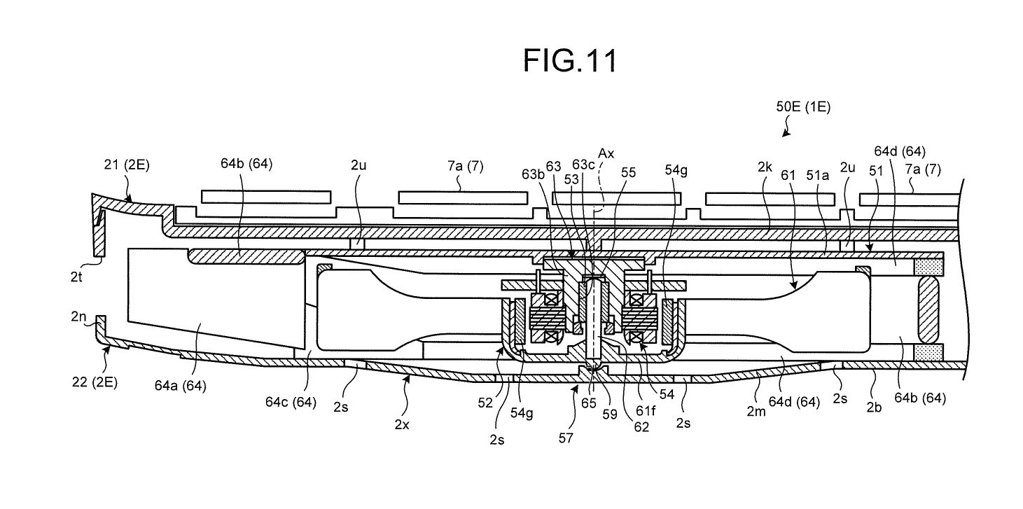

As it becomes apparent when FIG. 11 is compared with FIG. 8, a fan unit 50E housed in a second housing 2E of an electronic device 1E according to a fifth embodiment has a similar structure to that of the fan unit 50B in the second embodiment. Accordingly, the fifth embodiment can yield similar results (effects) based on a similar structure to that in the second embodiment.

In the fifth embodiment, as illustrated in FIG. 11 as one example, on the outer circumferential side of the fan 61 of the fan unit 50E, a heat pipe 64b (a pipe, a pipe portion, a heat transporting portion, or a tube) of the cooling device 64 is wound. The portions serving as gaps between the heat pipe 64b and the second housing 2E and between the heat pipe 64b and the case component 51 are covered (sealed) with a film 64c (for example, an insulator or a sheet) or an elastic member 64d (for example, expandable material). In other words, in the fifth embodiment, as one example, a portion of the wall 51c of the fan unit 50E is configured by the heat pipe 64b and the film 64c, whereby the structure of the fan unit 50E is likely to be further simplified. Moreover, because the area of the heat pipe 64b exposed to the wind blown by the fan 61 becomes larger, the cooling performance of the cooling device 64 is likely to be further increased.

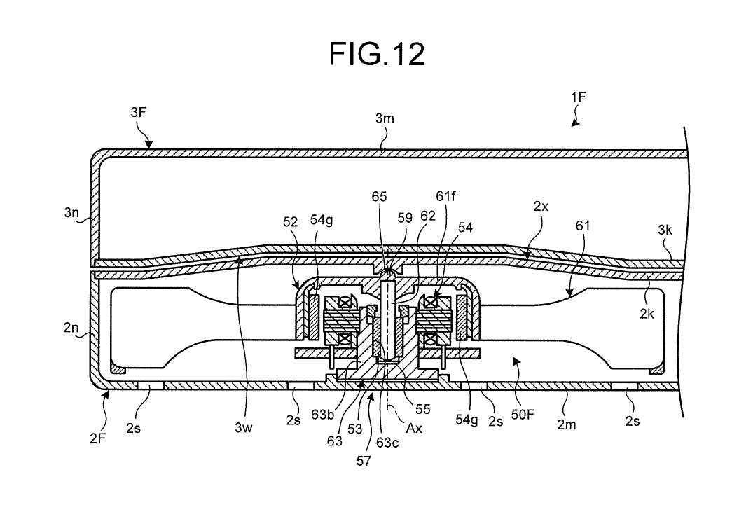

As it becomes apparent when FIG. 12 is compared with FIG. 9, a fan unit 50F housed in a second housing 2F of an electronic device 1F according to a sixth embodiment has a similar structure to that of the fan unit 50C in the third embodiment. Accordingly, the sixth embodiment can yield similar results (effects) based on a similar structure to that in the third embodiment.

In the sixth embodiment, as illustrated in FIG. 12 as one example, a portion of the wall 2k of the second housing 2F corresponding to the fan unit 50F bulges out towards a first housing 3F, whereby the bulging portion 2x (a projecting portion) is provided. Corresponding to the bulging portion 2x, a recessed portion 3w that accommodates the bulging portion 2x is provided on the wall 3k of the first housing 3F. In accordance with such a structure, as one example, an increase in the thickness of the second housing 2F due to the fan unit 50F is compensated by the reduction in the thickness of the first housing 3F, whereby an increase in the thickness of the electronic device 1F is likely to be suppressed in a state where the first housing 3F and the second housing 2F are folded (an overlapping state).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Furthermore, the structures and shapes in the embodiments described above can be implemented while partially replaced with one another. The specifications (such as the structure, type, direction, shape, size, length, width, thickness, height, number of pieces, arrangement, position, and material) of each of the structures and shapes can be implemented with appropriate changes. Additionally, the embodiments are applicable to a structure in which a fan unit is provided not on the housing but on a substrate.

1. A television receiver comprising:
a display device comprising a display screen;
a housing configured to house therein at least a portion of the display device;
a fan unit configured to be positioned in the housing and positioned opposite the display screen with respect to the display device, and comprising a rotating portion comprising a fan;
a first wall extending in a direction intersecting a rotation axis of the fan on a side opposite the display screen with respect to the fan;
a second wall extending in the direction intersecting the rotation axis on a side opposite the first wall with respect to the fan; and
a supporting structure configured to be positioned between the first wall and the second wall at a part at which rotation center of the rotating portion is positioned.

2. The television receiver of claim 1, wherein the supporting structure comprises:
a portion of the rotating portion;
at least a portion of a rotary supporting portion configured to be provided to one of the first wall and the second wall, and to rotatably support the rotating portion;
a contacting portion configured to be provided on other of the first wall and the second wall, and to contact a rotation center of the rotating portion when at least one of the first wall and the second wall is deformed.

3. The television receiver of claim 2, wherein one of the rotating portion and the contacting portion is provided with a projecting portion and other of the rotating portion and the contacting portion is provided with a recessed portion configured to accommodate the projecting portion.

4. The television receiver of claim 1, wherein the supporting structure is configured to be provided to at least one of the first wall and the second wall, and comprises a second projecting portion configured to be positioned in an opening provided at the rotation center of the rotating portion.

5. The television receiver of claim 4, wherein the second projecting portion is configured to extend over between the first wall and the second wall.

6. The television receiver of claim 4, wherein the rotating portion is rotatably supported by the second projecting portion.

7. The television receiver of claim 1, wherein at least one of the first wall and the second wall is a wall configuring at least a portion of the housing.

8. The television receiver of claim 7, wherein the fan unit is configured to be positioned in the housing at a corner of the housing.

9. An electronic device comprising:
a housing;
a fan unit configured to be provided in the housing, and comprising a rotating portion comprising a fan;
a first wall of the housing, the first wall extending in a direction intersecting a rotation axis of the fan at one side in an axis direction of the rotation axis;
a second wall of the housing, the second wall extending in a direction intersecting the rotation axis of the fan at other side in the axis direction of the rotation axis; and
a supporting structure configured to be positioned between the first wall and the second wall at a portion at which rotation center of the fan is positioned.

10. An electronic device comprising:
a housing;
a fan unit configured to be provided in the housing, and comprising a rotating portion comprising a fan;
a first wall of the housing, the first wall extending in a direction intersecting a rotation axis of the fan on one side in an axis direction of the rotation axis;
a second wall of the housing, the second wall extending in a direction intersecting the rotation axis of the fan on other side in the axis direction of the rotation axis; and
a supporting structure configured to be positioned between the first wall and the second wall, and to prevent a part of the first wall on one side in the axis direction of the rotation axis and a part of the second wall on other side in the axis direction of the rotation axis from coming close to each other.

11. The electronic device of claim 10, further comprising:
a third wall configured to be positioned between the first wall and the second wall, and to cover an outer circumferential side of the fan, wherein
the supporting structure is positioned closer to the rotation axis than the third wall.
